(19) United States
(12) Patent Application Publication
(10) Pub. No.: US 2004/0096757 A1
(43) Pub. Date: May 20, 2004

(54) Photosensitive resin compositon, photosesitive resist for color filter, and process for producing color filter

(76) Inventors: Hiroyuki Tokuda, Sakura-shi (JP); Yasunobu Hirota, Ichihara-shi (JP); Hidenobu Ishikawa, Ichihara-shi (JP)

Correspondence Address: ARMSTRONG, KRATZ, QUINTOS, HANSON & BROOKS, LLP, 1725 K STREET, NW, SUITE 1000, WASHINGTON, DC, 20006, US

(21) Appl. No.: 10/471,751

(22) PCT Filed: Mar. 27, 2001
(86) PCT No.: PCT/JP01/02441

(51) Int. Cl. G03F 7/40; G03F 7/033; G03F 7/004; G03F 7/075; C08F 2/48; C08L 33/14

(52) U.S. Cl. 430/8; 430/280.1; 430/285.1; 430/284.1; 430/286.1; 430/292; 430/293; 430/294; 430/321; 430/326; 430/320; 430/328; 430/910; 430/926; 430/954

(57) ABSTRACT

An object of the present invention is to provide a photosensitive resin composition or a photosensitive resist for color filters which is superior in heat resistance, water resistance, solvent resistance, chemical resistance, and also transparency, and a method for producing color filters using them. The present invention relates to a photosensitive resin composition comprising a vinyl polymer (A) having at least one cyclocarbonate group and at least one carboxyl group in the molecule and a compound (B) having at least two ethylenically unsaturated double bonds in the molecule as a main component, which can introduce crosslinked structures by photocuring and thermosetting, a photosensitive resist for color filters comprising the photosensitive resin composition and a colorant, and a method for producing a color filter, using the photosensitive resist for color filters.

### TECHNICAL FIELD

The present invention relates to a photosensitive resin composition, a photosensitive resist for color filters, and a method for producing color filters. More particularly, the present invention relates to a photosensitive resin composition which is suitable for uses requiring the durability after a patterning step by a development process, a photosensitive resist for color filters with excellent durability, and a method for producing color filters. Examples are coating compositions, printing ink, colored display panels using them, and products wherein a colored image is formed on a substrate such as color proofs. Furthermore, color filters used in color liquid crystal displays, color scanners and solid-state image sensing devices are good examples of this invention.

### BACKGROUND ART

It is well known that introduction of a crosslinked structure originating from functional groups is effective in addition to that originating from an ethylenically unsaturated double bond, to improve the durability of a cured coating film made from a conventional photosensitive resin composition.

An epoxy group is a representative of the “other functional groups”. The epoxy group can effectively form a crosslinked structure by the homopolymerization of itself and reaction with a compound having an amino group, a hydroxyl group or a carboxyl group. However, since the epoxy group is highly reactive, a photosensitive resin composition having the epoxy group did not have a good storage stability, and thus it was difficult to formulate into a one-pack composition.

To solve this problem, Japanese Patent Application, First Publication No. Hei 4-175359 proposes a thermosetting resin composition containing a compound having a 2-oxo-1,3-dioxoran-4-yl group, which can give a coating film with superior performance in acid resistance, weatherability and smoothness. However, since this composition does not include an ethylenically unsaturated double bond, it merely occurs the photocuring reaction and cannot be cured in a non-heating process, and thus the resulting coating film is not good at durability.

With recent increases in the use of ways, photosensitive resins have become widely used as a patterning material. Among these, an alkali-developable patterning material must be soluble in an aqueous alkali solution and, therefore, a resin composition containing a compound having a carboxyl group is generally used. However, a functional group such as a carboxyl group could be a cause of poor water resistance and poor chemical resistance in end use.

Therefore, Japanese Patent Application, First Publication No. Sho 60-217230 or Japanese Patent Application, First Publication No. Hei 6-192389 proposes that carboxylic acid be consumed by the reaction between a carboxyl group and an epoxy group using a compound having a carboxyl group in combination with a compound having an epoxy group capable of reacting with the carboxyl group, and then the heat resistance and mechanical properties can be improved by introducing crosslinked structures formed by this reaction.

The use of a compound having both an epoxy group and a carboxyl group in one molecule is particularly effective for improving the durability because a crosslinked structure can be, in this case, ultimately formed between the epoxy group and the carboxyl group.

However, of course this compound also is so reactive between the epoxy group and the carboxyl group that a photosensitive resin composition containing this compound is inferior in stability during production and storage, and thus it is difficult to formulate into a one-pack composition. Therefore it results the alkali development worse.

It is well known that a photosensitive resist prepared by adding photopolymerizable compound and photopolymerization initiator to a resin composition containing synthetic resins and pigments dispersed therein using dispersants, is one of the conventional photosensitive resin composition using colorants such as pigments and dyes.

It is also well known that a method for forming a colored picture element that carries out from applying the above composition on a base material, drying the composition, exposing the composition to light via a mask having a picture element pattern to form a picture element pattern, and heating, thereby to fix the picture element.

Applications of these photosensitive resists include color filters used in color liquid crystal displays, in color scanners and in solid-state image sensing devices.

Since materials for color filters must have characteristics which satisfy requirements in the manufacturing process of color liquid crystal displays, pigments have dominantly been used as colorants in these days.

In order to reconcile physical properties of the coating film, such as good solvent resistance and heat resistance, and a property to ease of alkali development, and moreover, to improve performances of the photosensitivity resin composition, various methods have been reported. For example, Japanese Patent Application, First Publication No. Hei 10-316721 proposes that, by introducing an alicyclic epoxy group into a binder resin, a reaction occurs with a carboxyl group and finally the system consumes unnecessary carboxylic acids and, furthermore, a crosslinked structure formed by this reaction is introduced, thereby the solvent resistance and heat resistance are improved.

These photosensitive resists are superior in physical properties of the coating film of the cured picture element portion. Nevertheless those are insufficient in stability during production and storage because of too high reactivity between the epoxy group and the carboxyl group, thus affect a problem such as reduction in ease of alkali development.

In addition to the above patents, Japanese Patent Application, First Publication No. Hei 5-39336 proposes a radiation curable resin composition containing a compound having a 2-oxo-1,3-dioxoran-4-yl group, and the coating film using this composition is superior in water resistance, solvent resistance, chemical resistance, heat resistance and curability. However, since this composition has a resin backbone mainly composed of an epoxy resin, it cannot disperse pigments well, and the transparency decreases.

### DISCLOSURE OF INVENTION

An object of the present invention is to provide a photosensitive resin composition, a photosensitive resist for color filters, and a method for producing color filters, which is particularly superior in heat resistance, water resistance, solvent resistance and chemical resistance, and also has good dispersibility of the pigment during the process without loss of transparency.

To overcome the above-mentioned drawbacks in the prior art, the present inventors have intensively researched about photosensitive resin compositions which have superior heat resistance, water resistance, solvent resistance, and chemical resistance and also have good dispersion stability of the pigment, and which does not cause deterioration of optical transparency. As a result, they found that the drawbacks of the prior art could be solved by using a photosensitive resin composition comprising a vinyl polymer having at least one 2-oxo-1,3-dioxoran-4-yl group and at least one carboxyl group in the molecule and a compound having at least two ethylenically unsaturated double bonds in the molecule as a main component, and thus the present invention has been completed.

The present invention provides a photosensitive resin composition comprising a vinyl polymer (A) having at least one 2-oxo-1,3-dioxoran-4-yl group and at least one carboxyl group in the molecule (hereinafter referred to as a vinyl polymer (A)), and a compound (B) having at least two ethylenically unsaturated double bonds in the molecule, as main components. Also, the present invention provides a photosensitive resist for color filters comprising a vinyl polymer (A) having at least one 2-oxo-1,3-dioxoran-4-yl group (hereinafter referred to as a cyclocarbonate group) and at least one carboxyl group in the molecule, a compound (B) having at least two ethylenically unsaturated double bonds in the molecule, and a colorant (C) as main components. Furthermore, the present invention provides a method for producing color filters using the above photosensitive resist for color filters.

### BEST MODE FOR CARRYING OUT THE INVENTION

The photosensitive resin composition of the present invention will be described in detail below.

First, the vinyl polymer (A) will be described.

The cyclocarbonate group in the vinyl polymer (A) is represented by the following general formula:

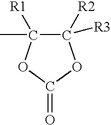

wherein R1, R2 and R3 may be the same or different and represent a hydrogen atom or an alkyl group having 1 to 4 carbon atoms.

The vinyl polymer (A) is obtained by copolymerizing a monomer having at least one cyclocarbonate group and an ethylenically unsaturated double bond in the molecule (hereinafter referred to as a monomer having a cyclocarbonate group and an ethylenically unsaturated double bond) and a monomer having at least one carboxyl group and an ethylenically unsaturated double bond in the molecule (hereinafter referred to as a monomer having a carboxyl group and an ethylenically unsaturated double bond) as essential components.

The monomer having a cyclocarbonate group and an ethylenically unsaturated double bond include compounds represented by the following general formula:

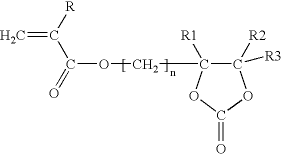

wherein R represents a hydrogen atom or a methyl group, R1, R2 and R3 may be the same or different and represent a hydrogen atom or an alkyl group having 1 to 4 carbon atoms, and n represents an integer of 1 to 6.

Specific examples are 2,3-carbonatepropyl (meth)acrylate, 2-methyl-2,3-carbonate propyl(meth)acrylate, 3,4-carbonate butyl(meth)acrylate, 3-methyl-3,4-carbonate butyl(meth)acrylate, 4-methyl-3,4-carbonate butyl(meth)acrylate, 3-methyl-3,4-carbonate butyl(meth)acrylate, 6,7-carbonate hexyl(meth)acrylate, 5-ethyl-5,6-carbonate hexyl(meth)acrylate, and 7,8-carbonate octyl(meth)acrylate; and 2,3-carbonate propyl vinyl ether, methyl-2,3-carbonatepropyl maleate, and methyl-2,3-carbonatepropyl crotonate. These monomers having a cyclocarbonate group and an ethylenically unsaturated double bond can be used alone, or two or more kinds thereof can be used in combination.

Examples of the monomer having a carboxyl group and an ethylenically unsaturated double bond include ethylenically unsaturated mono- and dicarboxylic acids such as acrylic acid, methacrylic acid, coumaric acid, itaconic acid, maleic acid, and fumaric acid; monoalkyl maleate ester, monoalkyl fumarate ester or monoalkyl itaconate ester; and those obtained by adding an acid anhydride such as phthalic anhydride, succinic anhydride or trimellitic anhydride to a hydroxyl group-containing compound.

The vinyl polymer (A) can be obtained by copolymerizing the monomer having a cyclocarbonate group and an ethylenically unsaturated double bond and the monomer having a carboxyl group and an ethylenically unsaturated double bond with other monomers having an ethylenically unsaturated double bond capable of copolymerizing with these monomers (hereinafter referred to as a copolymerizable monomer having an ethylenically unsaturated double bond).

Examples of the copolymerizable monomer having an ethylenically unsaturated double bond include:

(1) acrylate esters having a C₁₋₂₂ alkyl group, such as methyl acrylate, ethyl acrylate, propyl acrylate, butyl acrylate, hexyl acrylate, heptyl acrylate, octyl acrylate, nonyl acrylate, decyl acrylate, dodecyl acrylate, tetradecyl acrylate, hexadecyl acrylate, stearyl acrylate, octadecyl acrylate, and docosyl acrylate, and methacrylate esters having the same alkyl group;

(2) acrylate esters having an alicyclic alkyl group, such as cyclohexyl acrylate, isobomyl acrylate, dicyclopentanyl acrylate, and dicyclopentenyloxyethyl acrylate, and methacrylate esters having the same alicyclic alkyl group, and acrylate or methacrylate esters of tetrahydrofurfuryl alcohol and ε-caprolatone adduct;

(3) acrylate esters having an aromatic ring, such as benzoyloxyethyl acrylate, benzyl acrylate, phenylethyl acrylate, phenoxyethyl acrylate, phenoxydiethylene glycol acrylate, and 2-hydroxy-3-phenoxypropyl acrylate, and methacrylate esters having the same aromatic ring;

(4) acrylate esters having a hydroxyalkyl group, such as hydroxyethyl acrylate, hydroxypropyl acrylate, and glycerol acrylate, and methacrylate esters having the same hydroxyalkyl group, lactone-modified hydroxyethyl acrylates or methacrylates, an acrylate ester having a polyalkylene glycol group, such as polyethylene glycol acrylate or polypropylene glycol acrylate, and a methacrylate ester having the same polyalkylene glycol group;

(5) glycidyl acrylate, glycidyl methacrylate, glycidyl α-ethylacrylate, glycidyl α-n-propylacrylate, glycidyl α-n-butylacrylate, 3,4-epoxybutyl acrylate, 3,4-epoxybutyl methacrylate, 4,5-epoxypentyl methacrylate, 6,7-epoxypentyl acrylate, 6,7-epoxypentyl methacrylate, 6,7-epoxypentyl α-ethylacrylate; alicyclic epoxy compounds such as 3,4-epoxycyclohexyl acrylate, 3,4-epoxycyclohexyl methacrylate, lactone-modified acrylic acid-3,4-epoxycyclohexyl, 3,4-epoxycyclohexyl lactone-modified methacrylate, and vinylcyclohexene oxide, and compounds having both a glycidyl group and an ethylenically unsaturated double bond in the molecule obtained by reacting compounds having two or more alicyclic epoxy groups in the molecule with compounds having both an ethylenically unsaturated double bond and a group having reactivity with an alicyclic epoxy group in the molecule; and compounds having a glycidyl group and an ethylenically unsaturated double bond represented by the following general formula:

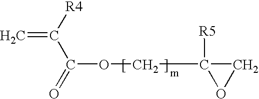

wherein R4 represents a hydrogen atom or a methyl group, R5 represents an alkyl group having 1 to 5 carbon atoms, and m represents an integer of 1 to 6, such as acrylate ester or methacrylate ester wherein R4 is hydrogen or a methyl group, and a lower alkyl group R5 is methyl, propyl, isopropyl, isobutyl, or amyl;

(6) fluorine-containing α-olefins such as vinyl fluoride, vinylidene fluoride, trifluoroethylene, chlorotrifluoroethylene, bromotrifluoroethylene, pentafluoropropylene, and hexafluoropropylene; (per)fluoroalkyl•perfluorovinyl ethers having a C₁₋₁₈ (per)fluoroalkyl group, such as trifluoromethyl trifluorovinyl ether, pentafluoroethyl trifluorovinyl ether, or heptafluoropropyl trifluorovinyl ether; and (per)fluoroalkyl (meth)acrylate having a C₁₋₁₈ (per)fluoroalkyl groups, such as 2,2,2-trifluoroethyl (meth)acrylate, 2,2,3,3-tetrafluoropropyl (meth)acrylate, 1H, 1H,5H-octafluoropentyl (meth)acrylate, 1H, 1H,2H,2H-heptadecafluorodecyl (meth)acrylate, and perfluoroethyloxyethyl (meth)acrylate;

(7) silyl group-containing (meth)acrylates such as γ-methacryloxypropyltrimethoxysilane;

(8) N,N-dialkylaminoalkyl (meth)acrylates such as N,N-dimethylaminoethyl (meth)acrylate, N,N-diethylaminoethyl (meth)acrylate, and N,N-diethylaminopropyl (meth)acrylate;

(9) acrylonitriles or methacrylonitriles;

(10) acrylamides or alkyd-substituted amide thereof;

(11) unsaturated dicarboxylate esters such as dimethyl fumarate, diethyl fumarate, dibutyl fumarate, dimethyl itaconate, dibutyl itaconate, methylethyl fumarate, methylbutyl fumarate, and methylethyl itaconate;

(12) styrene derivatives such as styrene, α-methylstyrene, and chlorostyrene;

(13) diene-based compounds such as butadiene, isoprene, piperylene, and dimethylbutadiene;

(14) unsaturated ketones such as methyl vinyl ketone and butyl vinyl ketone; and

(15) vinyl ethers such as methyl vinyl ether and butyl vinyl ether.

Among these monomers having a copolymerizable ethylenically unsaturated double bond, a (meth)acrylate ester having an aromatic ring is preferable and (meth)acrylic acid benzyl ester (hereinafter referred to as benzyl (meth)acrylate) is particularly preferable in view of the dispersibility of the pigment.

These monomers having a copolymerizable ethylenically unsaturated double bond can be used in polymerization only one monomer, or two or more kinds thereof in combination.

The vinyl polymer (A) is preferably an acrylic resin containing, as a main component, a monomer having a (meth)acryloyl group among a monomer having a cyclocarbonate group and an ethylenically unsaturated double bond, a monomer having a carboxyl group and an ethylenically unsaturated double bond and a monomer having a copolymerizable ethylenically unsaturated double bond, which is optionally copolymerized with other monomers having an ethylenically unsaturated double bond, in view of heat resistance, light resistance and transparency.

As described above, the vinyl polymer (A) is obtained by copolymerizing a monomer having a cyclocarbonate group and an ethylenically unsaturated double bond, a monomer having a carboxyl group and an ethylenically unsaturated double bond, and a monomer having a copolymerizable ethylenically unsaturated double bond. Although the copolymerization form is not specifically limited, e.g., the vinyl polymer can be prepared by a radical polymerization method in the presence of a catalyst (polymerization initiator). As the copolymerization method, for example, known methods can be used such as bulk polymerization method, solution polymerization method, suspension polymerization method, and emulsion polymerization method. The resulting vinyl polymer (A) may be a random copolymer, a block copolymer, or a graft copolymer.

Examples of the solvent, which can be used in the solution polymerization method, include:

(1) ketone solvents such as acetone, methyl ethyl ketone, methyl-n-propyl ketone, methyl isopropyl ketone, methyl-n-butyl ketone, methyl isobutyl ketone, methyl-n-amyl ketone, methyl-n-hexyl ketone, diethyl ketone, ethyl-n-butyl ketone, di-n-propyl ketone, diisobutyl ketone, cyclohexanone, and phorone;

(2) ether solvents such as ethyl ether, isopropyl ether, n-butyl ether, diisoamyl ether, ethylene glycol dimethyl ether, ethylene glycol diethyl ether, diethylene glycol dimethyl ether, diethylene glycol, dioxane, and tetrahydrofuran; and

(3) ester solvents such as ethyl formate, propyl formate, n-butyl formate, ethyl acetate, n-propyl acetate, isopropyl acetate, n-butyl acetate, n-amyl acetate, ethylene glycol monomethyl ether acetate, ethylene glycol monoethyl ether acetate, diethylene glycol monomethyl ether acetate, diethylene glycol monoethyl ether acetate, propylene glycol monomethyl ether acetate, and ethyl-3-ethoxypropionate.

As the catalyst, known radical polymerization initiators can be used. Examples of the radical polymerization initiator include azo compounds such as 2,2′-azobisisobutyronitrile, 2,2′-azobis-(2,4-dimethylvaleronitrile), and 2,2′-azobis-(4methoxy-2,4-dimethylvaleronitrile); organic peroxides such as benzoyl peroxide, lauroyl peroxide, t-butyl peroxypivalate, 1,1′-bis-(t-butylperoxy)cyclohexane, t-amylperoxy-2-ethylhexanoate, and t-hexylperoxy-2-ethylhexanoate; and hydrogen peroxide.

When using the organic peroxide as the radical polymerization initiator, the organic peroxide can be used in combination with a reducing agent resulted Sas a redox type initiator.

The amount of the cyclocarbonate group of the vinyl polymer (A) is preferably from 1 to 50% by weight, and particularly preferably from 2 to 40% by weight, in terms of a numerical value calculated based on the amount of the monomer having a cyclocarbonate group and an ethylenically unsaturated double bond. When the amount of the cyclocarbonate group is less than 1% by weight, the effect exerted by the crosslinking reaction between the monomesr having a cyclocarbonate group and an ethylenically unsaturated double bond cannot be expected. On the other hand, when the amount exceeds 50% by weight, an intermolecular interaction between cyclocarbonate groups increases, thus inconveniences occur such as deterioration of the solubility in the solvent and deterioration of the dispersibility of the pigment.

The amount of the carboxyl group of the vinyl polymer (A) is preferably from 3 to 40% by weight, and particularly preferably from 5 to 35% by weight, in terms of a numerical value calculated based on the amount of the monomer having a carboxyl group and an ethylenically unsaturated double bond. When the amount is less than 3% by weight, the solubility of the monomer having a carboxyl group and an ethylenically unsaturated double bond in an aqueous alkali solution becomes insufficient. On the other hand, when the amount exceeds 40% by weight, the solubility in the aqueous alkali solution becomes too high, thus making it difficult to form a pattern of the coating film.

The numerical value of an acid value (the number of milligrams of potassium hydroxide required to neutralize the acid content in 1 g of a sample, which is determined by a prescribed method) of the vinyl polymer (A) can be selected for the purposes of the formation of the coating film. The acid value is not specifically limited as long as the development can be carried out by an aqueous alkali solution, but is preferably within a range from 20 to 250 mg KOH/g.

The vinyl polymer (A) preferably has additional ethylenically unsaturated double bond in the molecule. The vinyl polymer (A) itself can be provided with radiation curability by introducing an ethylenically unsaturated double bond into the vinyl polymer (A). The photocuring sensitivity can be improved by carrying out the crosslinking reaction between the introduced ethylenically unsaturated double bond and the polymerizable compound (B).

The vinyl polymer (A) preferably has a hydroxyl group. The vinyl polymer (A) having a hydroxyl group can be obtained by copolymerizing a monomer having a cyclocarbonate group and an ethylenically unsaturated double bond, a monomer having a carboxyl group and an ethylenically unsaturated double bond, and a monomer having at least one hydroxyl group and an ethylenically unsaturated double bond in the molecule. By using the vinyl polymer (A) having a hydroxyl group, the solubility in the aqueous alkali solution is so improved that a coating film with a sharp picture element pattern formed thereon can be obtained.

The molecular weight of the vinyl polymer (A) is not specifically limited, but is preferably 2,000 or more, and more preferably from 3,500 to 50,000, in terms of number-average molecular weight (hereinafter referred to as Mn) calculated based on polystyrene, so as to maintain coating film performances. When the number-average molecular weight is less than 2,000, it becomes difficult to form a uniform coating film and to give various coating film performances. On the other hand, when the number-average molecular weight exceeds 50,000, the viscosity of the resin increases, thus workability of coating becomes worse in some coating method.

A ratio of the weight-average molecular weight (hereinafter referred to as Mw) to Mn, (Mw/Mn: molecular weight distribution), is not specifically limited, but is preferably 6.0 or less, and more preferably 5.0 or less. When Mw/Mn exceeds 6.0, it becomes difficult to form a uniform coating film, similar to the case of the above-mentioned in molecular weight. In addition, the viscosity of the resin increases so that the coating workability tends to be worse in some coating method and, furthermore, the solubility in the aqueous alkali solution tends to deteriorate.

The molecular weight can be appropriately selected according to the thickness of the coating film to be formed, and purposes and conditions of the formation of the coating film, such as coating method.

The compound having at least two ethylenically unsaturated double bonds in the molecule (hereinafter referred to as a polymerizable compound (B)) will be described below.

Examples of the polymerizable compound (B) include trimethylolethane triacrylate, trimethylolpropane triacrylate, trimethylolpropane diacrylate, neopentyl glycol di(meth)acrylate, pentaerythritol tetra(meth)acrylate, pentaerythritol tri(meth)acrylate, dipentaerythritol hexa(meth)acrylate, dipentaerythritol penta(meth)acrylate, hexanediol di(meth)acrylate, trimethylolpropanetri(acryloyloxypropyl) ether, tri(acryloyloxyethyl) isocyanurate, tri(acryloyloxyethyl) cyanurate, glycerin tri(meth)acrylate, epoxy (meth)acrylates (for example, reaction products of epoxy resins such as phenol•novolak epoxy resin, cresol•novolak epoxy resin or bisphenol A epoxy resin, and (meth)acrylic acid), urethane (meth)acrylates composes of polyols such as ethylene glycol, polyethylene glycol, polypropylene glycol, polytetramethylene glycol, polyethoxydiol of bisphenol A, polyester polyol, polybutadiene polyol, and polycarbonate polyol, organic polyisocyanates, and organic polyisocyanate such as tolylene diisocyanate, xylylene diisocyanate, isophorone diisocyanate, and hexamethylene diisocyanate and hydroxyl group-containing (meth)acrylates such as 2-hydroxyethyl (meth)acrylate, 2-hydroxypropyl (meth)acrylate, and 1,4-butanediolmono (meth)acrylate, and polyester (meth)acrylates which are reaction products of polyester polyols which are obtained by reaction of polybasic acid compounds or anhydrides thereof such as maleic acid, succinic acid, adipic acid, isophthalic acid, phthalic acid, terephthalic acid, tetrahydrophthalic acid, hexahydrophthalic acid and anhydrides thereof and polyols such as ethylene glycol, propylene glycol, 3-methyl-1,5-pentanediol, neopentyl glycol, 1,6-hexanediol, trimethylolpropane, and pentaerythritol, and (meth)acrylic acid.

Among these polymerizable compounds (B), trimethylolpropane tri(meth)acrylate, pentaerythritol tetra(meth)acrylate, dipentaerythritol hexa(meth)acrylate and dipentaerythritol penta(meth)acrylate are particularly preferable in view of photocuring sensitivity.

The amount of the polymerizable compound (B) can be within a range from 5 to 90% by weight based on the resin component of the photosensitive resin composition of the present invention. As the polymerizable compound (B), only one of the above-mentioned specific compounds can be used, or two or more kinds thereof can be used in combination. In the case in which the photosensitive resin composition of the present invention is used as a photosensitive resist for color filters so that pattern forming characteristics are required, the polymerizable compound is preferably used in an amount within a range from 10 to 70% by weight. In this case, when the polymerizable compound (B) exceeds 70% by weight, the desired alkali solubility of the present invention also deteriorates. On the other hand, when the amount is less than 10% by weight, a cured coating film having desired physical properties is not easily obtained, and it becomes difficult to form a pattern, therefore this amount is not preferable.

The photosensitive resin composition of the present invention itself can be used in photosensitive coating compositions, adhesives and patterning materials.

The photosensitive resin composition can appropriately be added colorants such as pigments and dyes. The photosensitive resin composition containing colorants is preferably used in coating compositions, printing ink and resists, particularly photosensitive resists for color filters.

The cyclocarbonate group in the vinyl polymer (A) has the effect of much improving the dispersibility of the pigment as the functional group's polarity.

In order to accelerate the crosslinking reaction by ring opening of the cyclocarbonate group, a ring opening catalyst can be used.

Examples of the ring opening catalyst include ring opening catalysts of the cyclocarbonate group and ring opening catalysts of the epoxy group. Specific examples thereof include quaternary ammonium salts such as tetramethylammonium bromide, trimethylbenzylammonium hydroxide, 2-hydroxypyridine, trimethylbenzylammonium methoxide, phenyltrimethylammonium chloride, phenyltrimethylammonium bromide, phenyltrimethylammonium hydroxide, phenyltrimethylammonium iodide, phosphocholine chloride sodium salt, stearylammonium bromide, tetra-n-amylammonium iodide, tetra-n-butylammonium bromide, tetra-n-methylammonium hydroxide, tetra-n-butylammonium phosphate, tetra-n-decylammonium trichloride, tetraethylammonium hydroxide, tetraethylammonium tetrafluoroborate, acetylcholine bromide, alkyldimethylbenzylammonium chloride, benzylcholine bromide, benzyl-n-butylammonium bromide, betaine, butyryl chloride, bis(tetra-n-butylammonium)dichromate, and trimethylvinylammonium bromide; phosphonium salts such as allyltriphenylphosphonium chloride, n-amyltriphenylphosphonium bromide, benzyltriphenylphosphonium chloride, bromomethyltriphenylphosphonium bromide, 2-dimethylaminoethyltriphenylphosphonium bromide, ethoxycarbonylphosphonium bromide, n-heptyltriphenylphosphonium bromide, methyltriphenylphosphonium bromide, tetrakis(hydroxymethyl)phosphonium sulfate, and tetraphenylphosphonium bromide; acid catalysts such as phosphoric acid, p-toluenesulfonic acid, and dimethylsulfiric acid; and carbonate salt such as calcium carbonate.

When the photosensitive resin composition of the present invention is cured by radiation such as light, a photopolymerization initiator for initiation of the polymerization reaction by means of light must be used.

As the photopolymerization initiator, known photopolymerization initiators can be used. Examples of known photopolymerization initiator include:

(1) benzophenones such as benzophenone, 3,3-dimethyl-4-methoxybenzophenone, 4,4′-bisdimethylaminobenzophenone, 4,4′-bisdiethylaminobenzophenone, 4,4-dichlorobenzophenone, Michler's ketone, and 3,3′,4,4′-tetra(t-butylperoxycarbonyl)benzophenone;

(2) xanthones and thioxanthones, such as xanthone, thioxanthone, 2-methylthioxanthone, 2-isopropylthioxanthone, 2-chlorothioxanthone, 2,4-diethylthioxanthone, 2,4-dimethylthioxanthone, and thioxanthone-4-sulfonic acid;

(3) acyloin ethers such as benzoin, benzoin methyl ether, benzoin ethyl ether, benzoin isopropyl ether, benzoin-n-butyl ether, benzoin isobutyl ether, and benzoin butyl ether;

(4) α-diketones such as benzyl and diacetyl;

(5) sulfides such as tetramethylthiuram monosulfide, tetramethylthiuram disulfide, and p-tolyl disulfide; and

(6) benzoic acids such as 4-dimethylaminobenzoic acid, methyl 4-dimethylaminobenzoate, ethyl 4-dimethylaminobenzoate, butyl 4-dimethylaminobenzoate, 4-dimethylaminobenzoic acid-2-ethylhexyl, and 4-dimethylaminobenzoic acid-2-isoamyl;

3,3′-carbonyl-bis(7-diethylamino)cumarin, 1-hydroxycyclohexyl phenyl ketone, 2,2-dimethoxy-1,2-diphenylethan-1-one, 2-methyl-1-[4-(methylthio)phenyl]-2-morpholinopropan-1-one, 2-benzyl-2-dimethylamino-1-(4-morpholinophenyl)-butan-1one, 2-hydroxy-2-methyl-1-phenylpropan-1-one, 2,4,6-trimethylbenzoyldiphenylphosphine oxide, 1-[4-(2-hydroxyethoxy)phenyl]-2-hydroxy-2methyl-1-propan-1-one, 1-(4-isopropylphenyl)-2-hydroxy-2-methylpropan-1-one, 1-(4dodecylphenyl)-2-hydroxy-2-methylpropan-1-one, 4-benzoyl-4′-methyldimethylsulfide, methoxyethylacetal, 1-phenyl-1,2-propanedione-2-(o-ethoxycarbonyl)oxime, 2-phenyl1,2-butanedione-2-(o-methoxycarbonyl)oxime, 1,3-diphenyl-propanetrione-2-(oethoxycarbonyl)oxime, 1-phenyl-3-ethoxy-propanetrione-2-(o-benzoyl)oxime, methyl o-benzoylbenzoate, bis(4-dimethylaminophenyl) ketone, p-dimethylaminoacetophenone, α,α-dichloro-4-phenoxyacetophenone, pentyl-4-dimethylaminobenzoate; biimidazoles such as 2,2′-bis(2-chlorophenyl)-4,4′,5,5′-tetrakis(4-ethoxycarbonylphenyl)-1,2′-biimidazole, 2,2′-bis(2-bromophenyl)-4,4′,5,5′-tetrakis(4-ethoxycarbonylphenyl)-1,2′-biimidazole, 2,2′-bis(2,4-dichlorophenyl)-4,4′,5,5′-tetraphenyl-1,2′-biimidazole, 2,2′-bis(2,4-dibromophenyl)-4,4′,5,5′-tetraphenyl-1,2′-biimidazole, and 2,2′-bis(2,4,6-tribromophenyl)-4,4′,5,5′-tetraphenyl-1,2′-biimidazole; p-dimethylaminoacetophenone, α,α-dichloro-4-phenoxyacetophenone, pentyl-4-dimethylaminobenzoate, 2,4-bis-trichloromethyl-6-[di-(ethoxycarbonylmethyl)amino]phenyl-S-triazine, 2,4-bis-trichloromethyl-6-(4ethoxy)phenyl-S-triazine, 2,4-bis-trichloromethyl-6-(3-bromo-4-ethoxy)phenyl-S-triazineanthraquinone, 2-t-butylanthraquinone, 2-amylanthraquinone, β-chloroanthraquinone, anthrone, benzanthrone, dibenzsuberone, methyleneanthrone, 4-azidobenzylacetophenone, 2,6-bis(p-azidobenzylidene)cyclohexane, 2,6-bis(p-azidobenzylidene)-4-methylcyclohexanone, naphthalenesulfonyl chloride, quinolinesulfonyl chloride, n-phenylthioacridone, 4,4-azobisisobutyronitrile, diphenyl disulfide, benzthiazole disulfide, triphenylphosphine, carbon tetrabromide, tribromophenylsulfone, benzoin peroxide, and combinations of photoreducing pigments such as eosin and methylene blue and reducing agents such as scorbic acid and triethanolamine.

Examples of commercially available products of the photopolymerization initiator include Irgacure 184, 149, 261, 369, 500, 651, 784, 819, 907, 1116, 1664, 1700, 1800, 1850, 2959, and 4043 and Darocur 1173 (manufactured by Ciba Speciality Chemicals Co.); Rucilin TPO (manufactured by BASF Co.); KAYACURE DETX, MBP, DMBI, EPA and OA (manufactured by NIPPON KAYAKU CO., LTD.); VICURE 10 and 55 (manufactured by STAUFFER Co., LTD.), TRIGONALPI (manufactured by AKZO Co., LTD.); SANDORY 1000 (manufactured by SANDOZ Co., LTD.); DEAP (manufactured by APJOHN Co., LTD.); and QUANTACURE PDO, ITX and EPD (manufactured by WARD BLEKINSOP Co., LTD.).

The photopolymerization initiator can be used in combination with a photosensitizer.

As the photosensitizer, known photosensitizers can be used. Examples of known photosensitizer include amines, ureas, sulfur-containing compounds, phosphorus-containing compounds, chlorine-containing compounds, and nitriles and other nitrogen-containing compounds.

Only one of these photopolymerization initiators and photosensitizers or two or more kinds thereof in combination can be used. The amount is not specifically limited, but is preferably from 0.1 to 20% by weight, and particularly preferably from 0.5 to 10% by weight, based on the polymerizable compound (B). When the amount is less than 0.1% by weight, the photosensitivity deteriorates. On the other hand, when the amount exceeds 20% by weight, deposition of crystals and deterioration of physical properties of the coating film occur and, therefore, it is not preferable.

If necessary, the photosensitive resin composition of the present invention can contain other components as long as the object of the present invention is not adversely affected and storage stability, water resistance, chemical resistance and heat resistance can be maintained.

Examples of other components include reactive diluents, curing catalysts, organic solvent, coupling agents, stabilizers (for example, antioxidants and ultraviolet absorbers) and various leveling agents (for example, silicone, fluorine and acrylic leveling agents). In order to improve ease of alkali development and thermocurability of the photosensitive resin composition of the present invention, polyacidic carboxylic acids and anhydrides thereof can be added as other components. Furthermore, epoxy compounds can be added to improve the thermal curability.

Examples of the reactive diluent include butoxyethyl (meth)acrylate, butoxyethylene glycol (meth)acrylate, 2-hydroxyethyl (meth)acrylate, 2-hydroxypropyl (meth)acrylate, 2-ethylhexyl (meth)acrylate, N-vinylpyrrolidone, 1-vinylimidazole, isobomyl (meth)acrylatete, tetrahydrofurfuryl (meth)acrylate, carbitol (meth)acrylate, phenoxyethyl (meth)acrylate, cyclopentadiene (meth)acrylate, N-vinylpyrrolidone, N-vinylformamide, N-vinylacetamide, and N-vinylmorpholine. Only one of these reactive diluents or two or more kinds thereof in combination can be used.

Examples of the coupling agent include silane coupling agents, titanium coupling agents, and aluminum coupling agents.

Among these, silane coupling agents are preferable because particularly excellent smoothness, adhesion, water resistance and solvent resistance are imparted to various materials.

Examples of the silane coupling agents include γ-(2-aminoethyl)aminopropyltrimethoxysilane, γ-(2aminoethyl)aminopropylmethyldimethoxysilane, γ-methacryloxypropyltrimethoxysilane, γ-glycidoxypropyltrimethoxysilane, β-(3,4-epoxycyclohexyl)ethyltrimethoxysilane, γ-mercaptopropyltrimethoxysilane, vinyltriacetoxysilane, vinyltrimethoxysilane, trimethoxysilylbenzoic acid, and γ-isocyanatopropyltriethoxysilane, and oligomers and polymers composed of these silane coupling agents.

Among these silane coupling agents, silane coupling agents having an epoxy group, such as γ-glycidoxypropyltrimethoxysilane and β-(3,4-epoxycyclohexyl)ethyltrimethoxysilane are preferable.

Only one of these coupling agents or two or more kinds thereof in combination can be used.

The amount of the coupling agent is preferably within a range from 0.1 to 30 parts by weight, and particularly preferably from 0.5 to 20 parts by weight, based on 100 parts by weight of the vinyl polymer (A). When the amount of the coupling agent is less than 0.1 parts by weight, the smoothness, adhesion with the substrate, water resistance and solvent resistance of the resulting coating film are insufficient. On the other hand, when the amount exceeds 30 parts by weight, not only can an improvement in adhesion not be expected, but also the curability of the resulting coating film deteriorates.

The photosensitive resin composition of the present invention can be obtained by uniformly mixing the above-mentioned components. As the mixing method, there can be used a solvent mixing method of dissolving these components in a proper solvent and mixing them. The solvent is not specifically limited as long as it dissolves the respective components and does not react with them.

As the solvent, there can be used the respective solvents used in the preparation of the vinyl polymer (A) as it is.

In the case of preparing the photosensitive resin composition of the present invention by the solvent mixing method, the order of mixing is not specifically limited. For example, the photosensitive resin composition of the present invention may be prepared by simultaneously dissolving all components in the solvent, or the photosensitive resin composition of the present invention may be prepared by separately dissolving the respective components in the same or different solvent to give two or more solutions, and then mixing these solutions.

The photosensitive resin composition of the present invention thus prepared can be used as coating compositions, adhesives and patterning materials as it is. A cured coating film superior in heat resistance, water resistance, solvent resistance and chemical resistance can be formed by applying the photosensitive resin composition on a base material.

When using the photosensitive resin composition of the present invention as the coating composition, it can be used as UV curable coating compositions and thermosetting coating compositions after mixing a vinyl polymer (A) and a polymerizable compound (B) as a binder resin with colorants and additives.

When using the photosensitive resin composition of the present invention as printing ink, it can be used as, for instance, UV curable ink, using a vinyl polymer (A), a polymerizable compound (B), and a solvent as the constituent components of a vehicle and adding a colorant and an auxiliary.

Next, we will describe the photosensitive resist for color filters of the present invention will be described below.

The photosensitive resist for color filters of the present invention comprises a vinyl polymer (A), a polymerizable compound (B), and a colorant (C) as an essential component.

The vinyl polymer (A) and the polymerizable compound (B) are as described above.

Examples of the colorant (C) include pigments, dyes, and other dyestuffs.

Examples of the pigment include organic pigments and inorganic pigments. Examples of the organic pigment include red pigments such as C.I. Pigment Red 9, C.I. Pigment Red 97, C.I. Pigment Red 122, C.I. Pigment Red 123, C.I. Pigment Red 149, C.I. Pigment Red 168, C.I. Pigment Red 177, C.I. Pigment Red 180, C.I. Pigment Red 192, C.I. Pigment Red 215,C.I. Pigment Red 216, C.I. Pigment Red 217, C.I. Pigment Red 220,C.I. Pigment Red 223, C.I. Pigment Red 224, C.I. Pigment Red 226, C.I. Pigment Red 227, C.I. Pigment Red 228, C.I. Pigment Red 240, C.I. Pigment Red 254, and C.I. Pigment Red 48:1; green pigments such as C.I. Pigment Green 7 and C.I. Pigment Green 36; blue pigments such as C.I. Pigment Blue 15, C.I. Pigment Blue 15:6, C.I. Pigment Blue 22, C.I. Pigment Blue 60, and C.I. Pigment Blue 64; violet pigments such as C.I. Pigment Violet 19, C.I. Pigment Violet 23,C.I. Pigment Violet 29, C.I. Pigment Violet 30,C.I. Pigment Violet 37, C.I. Pigment Violet 40, and C.I. Pigment Violet 50; yellow pigments such as C.I. Pigment Yellow 20,C.I. Pigment Yellow 24, C.I. Pigment Yellow 83, C.I. Pigment Yellow 86,C.I. Pigment Yellow 93, C.I. Pigment Yellow 109, C.I. Pigment Yellow 110, C.I. Pigment Yellow 117, C.I. Pigment Yellow 125, C.I. Pigment Yellow 137, C.I. Pigment Yellow 138, C.I. Pigment Yellow 139, C.I. Pigment Yellow 147, C.I. Pigment Yellow 148, C.I. Pigment Yellow 150, C.I. Pigment Yellow 153,C.I. Pigment Yellow 154, C.I. Pigment Yellow 166, C.I. Pigment Yellow 168, and C.I. Pigment Yellow 185; and black pigments such as C.I. Pigment Black 7. It is possible to observe individual pigment primary particles constituting aggregates, which cannot be observed in conventional pigments. When primary particles have an average particle diameter within a range from 0.01 to 0.10 μm, the pigment of the present invention is superior in dispersibility. The average particle diameter of primary particles of the pigment can be measured by a transmission electron microscope or a scanning electron microscope after subjecting the pigment to ultrasonic dispersion in a solvent. The average particle diameter of primary particles of the pigment in the present invention is a value obtained by taking a microphotograph of the pigment within the visual field of the microscope using a transmission electron microscope JEM-2010 (manufactured by JEOL, Ltd.), then determining each of longer diameters (major axes) of 50 primary pigment particles constituting an agglomerate on a two-dimensional image, and calculating an average thereof.

Examples of the inorganic pigment include barium sulfate, lead sulfate, titanium oxide, chrome yellow, red iron oxide, chromium oxide, and carbon black.

As the dye, various dyes can be used. There can be mentioned, for example, those described in “Senryou Binran” (Dye Manual) (edited by the Organic Synthesis Chemistry Association, 1970), “Shikizai Kougaku Handobukku” (Coloring Material Engineering Handbook) (edited by the Coloring Material Association, Asakura Shoten, 1989), “Kougyouyou Shikiso no Gijutsu to Shijou” (Technology and Market of Industrial Coloring Matter) (edited by CMC, 1983), and “Kagaku Binran Ouyou Kagaku Hen” (Chemistry Manual-Applied Chemistry Version) (edited by Japan Chemistry Society, Maruzen Shoten, 1986). Specific examples thereof include azo dyes, metal complex azo dyes, pyrazolone azo dyes, naphthoquinoene dyes, anthraquinone dyes, phthalocyanine dyes, carbonium dyes, quinoneimine dyes, methine dyes, cyanine dyes, indigo dyes, quinoline dyes, nitro dyes, xanthene dyes, thiazine dyes, azine dyes, oxazine dyes, and squarilium dyes.

Only one of these pigments and dyes or two or more kinds thereof in combination can be used.

In addition to the above-mentioned pigments and dyes, inorganic dyestuffs can be used as the colorant. Examples of the inorganic dyestuff include carbon-, titanium-, barium-, aluminum-, calcium-, iron-, lead- and cobalt-based inorganic dyestuffs.

The colorants are preferably pigments in view of the heat resistance and light resistance.

The content of the colorant in the photosensitive resist of the present invention is within a range from 5 to 80% by weight.

In order to disperse the pigment in the photosensitive resist for color filters, dispersants can be used. Examples of the dispersant include, but are not limited to, surfactants, intermediates of pigments, intermediates of dyes, and resin-type dispersants such as polyamide-based compounds and polyurethane-based compounds.

Examples of the commercially available product of the resin-type dispersant include DISPERBYC 130, DISPERBYC 161, DISPERBYC 162, DISPERBYC 163, DISPERBYC 170, EFKA 46, EFKA 47, and SOLSPERSE. Also resin-type dispersants such as acrylic- and polyethylene-based dispersants can be used.

In the case of dispersing the pigment, a disperser can be used. Examples of the disperser include a roll mill, ball mill, bead mill, atriter, and dispersion stirrer.

In the case of dispersing the pigment, a solvent is used. Examples of the solvent include, but are not limited to, aromatic solvents such as toluene, xylene and methoxybenzene; acetate solvents such as ethyl acetate, butyl acetate, propylene glycol monomethyl ether acetate, and propylene glycol monoethyl ether acetate; propionate solvents such as ethoxyethyl propionate; alcohol solvents such as methanol and ethanol; ether solvents such as butylcellosolve, propylene glycol monomethyl ether, diethylene glycol ethyl ether and diethylene glycol dimethyl ether; ketone solvents such as methyl ethyl ketone, methyl isobutyl ketone, and cyclohexanone; aliphatic hydrocarbon solvents such as hexane; nitrogen compound solvents such as N,N-dimethylformamide, γ-butyrolactam, N-methyl-2-pyrrolidone, aniline, and pyridine; lactone solvents such as γ-butyrolactone; carbamates such as mixture of methyl carbamate and ethyl carbamate in a mixing ratio of 48:52; and water.

In the photosensitive resist for color filter of the present invention, ring opening catalysts of a cyclocarbonate group, photopolymerization initiators, photosensitizers, reactive diluents, curing catalysts, organic solvent, coupling agents, stabilizers (for example, antioxidants and ultraviolet absorbers) and leveling agents can be added, in addition to the above-mentioned colorants and dispersants, similar to make the photosensitive resin composition.

In the photosensitive resist for color filters of the present invention, the reaction between both functional groups, a cyclocarbonate group and a carboxyl group, of the vinyl polymer (A) is suppressed at normal temperature and the exposure temperature during a preheating process, and the stability can be maintained until the process of forming a picture element portion by the development process is completed. During the heating process after the formation of the picture element portion, the cyclocarbonate group is reacted with the carboxyl group, thereby the crosslinked structures are introduced into the picture element portion, so that the solvent resistance, heat resistance and mechanical properties of the picture element portion can be improved. As described above, in the final heating process, the cyclocarbonate group is reacted with the carboxyl group, thereby the carboxyl groups are consumed, therefore it can be possible to improve deterioration of the water resistance and chemical resistance of the coating film caused by the carboxyl group.

From now we will discuss the method for producing color filters of the present invention, described below.

The method for producing color filters of the present invention comprises forming a resist layer on a transparent substrate using a photosensitive resist for color filters of the present invention; exposing the resist layer to light via a mask having a picture element pattern for color filters, thereby to photocure the resist layer; developing the resist layer to form a picture element portion; and heating the picture element portion, thereby to thermoset the picture element portion.

In the case in which the photosensitive resist contains a solvent in this method, after forming a resist layer, it is preheated under the heating conditions at a temperature of 50 to 150° C. for about 1 to 15 minutes so as to remove the solvent in the resist layer.

The color filters are mainly composed of a transparent substrate, a light-shielding picture element portion, referred to as a black matrix, provided on the transparent substrate, and a light-transmitting picture element portion for the three primary colors, red, green and blue, provided on the light-shielding thin film.

In the method for producing color filters, in order to form the picture element portion of three primary colors, red, green and blue, the processes of forming a resist layer, exposing of the resist layer to light, developing and heating the resist layer must be repeated three times.

Examples of the transparent substrate include materials such as glass plate and transparent plastic plate.

Examples of the method for formation of a layer of the photosensitive resist of the present invention on the surface of the transparent substrate include, but are not limited to, application and transfer methods. Application can be carried out by various methods such as a printing method, spray method, roll coating method, and rotary coating method. In the transfer process, a photosensitive resist is previously applied on a film base material and the photosensitive resist is transferred onto a glass substrate to form a photosensitive resist layer on the glass substrate.

In the exposure process, the photosensitive resist layer formed on the transparent substrate is exposed to light via a photo mask having a picture element pattern for color filter using a high-pressure mercury lamp. The photosensitive resist layer is photocured by this exposure process.

In the development process, the photosensitive resist layer is developed by contacting with a developing solution. As a result of the development, a carboxyl group in the non-exposed portion is neutralized and made soluble with an aqueous alkali solution, and thus the non-exposed portion is removed. Examples of the developing method include developing solution application method, dipping method, and spraying method.

After the development, the unnecessary portion is removed by washing with running water and air-drying with compressed air or compressed nitrogen, thus forming a picture element portion.

As the developing solution, an aqueous alkali solution is used. Examples of the aqueous alkali solution include aqueous solutions of sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, dimethylethanolamine, diethanolamine, triethanolamine, tetramethylammonium hydroxide, tetraethylammonium hydroxide, tetrabutylammonium hydroxide, pyrrole, piperidine, 1,8-diazabicyclo[5,4,0]-7-undecene, and 1,5-diazabicyclo[4,3,0]-5-nonane. Among these compounds, those which are hardly soluble in water can be used in the form of an aqueous solution wherein a solution of the compound dissolved in an organic solvent such as methanol, ethanol or isopropyl alcohol is diluted with water.

After forming the picture element portion, the picture element portion is thermoset by heating to a predetermined temperature, for example, 100 to 250° C. for a predetermined time using heating apparatuses such as a hot plate or oven. The picture element portion, which is superior in durability such as heat resistance, transparency or hardness, can be formed by thermosetting.

The color filter obtained by the method of the present invention has excellent durability and is used, for example, in color liquid crystal displays, color scanners, and solid-state image sensing devices.

### EXAMPLES

The following Examples further illustrate the present invention in detail; however the present invention is not limited to these Examples. In the Examples, parts and percentages are by weight unless otherwise specified. The performance test of the resulting coating film was carried out by the following procedures.

<Procedures for Performance Test and Appraisal Standard>

Storage Stability

25 g of each of the photosensitive resin compositions of the Examples described hereinafter was transferred into an airtight glass container and the viscosity was measured after storing at 40° C. for 24 hours. Samples which showed a change of less than 10% or less relative to initial viscosity were rated “A”, while samples which showed a change of 10% or more were rated “C”. With respect to the photosensitive resists of the Examples described hereinafter, the same operation was carried out. The viscosity was measured by a viscometer, Model E, manufactured by TOKIMEC INC.

Developing Characteristics

A coating film was formed by applying each of the photosensitive resin compositions of the Examples described hereinafter on a glass plate while rotating at 1000 rpm for 9 seconds using a spin coater, and drying at 60° C. for 5 minutes. The coating film was exposed to light at a dose of 200 mJ/cm² via a mask having a predetermined pattern using a high-pressure mercury lamp, developed in an aqueous 1.0 wt % sodium carbonate aqueous solution at 30° C., and then washed with pure water. We evaluated by these operations whether a pattern (residue) having a line width of 20 μm can be formed or not. With respect to the photosensitive resists of the Examples described hereinafter, the same operation was carried out. Samples which can form the pattern were rated “A”, while samples which cannot form the pattern were rated “C”.

Transparency

A coating film was formed by applying each of the photosensitive resin compositions of the Examples described hereinafter on a glass plate while rotating at 1000 rpm for 9 seconds using a spin coater, and drying at 60° C. for 5 minutes. The coating film was exposed to light at a dose of 200 mJ/cm² using a high-pressure mercury lamp, and then cured by subjecting to a heat treatment at 230° C. for 15 minutes. For an absorption spectrum of the coating film on the glass plate, a light transmittance at a range from 400 to 800 nm was measured based on the used glass plate itself. With respect to the photosensitive resists of the Examples described hereinafter, the same operation was carried out. Samples which showed a light transmittance of 95% or more were rated “A”, while samples which showed a light transmittance of less than 95% were rated “C”.

Heat Resistance-1

The chromaticity (hereinafter referred to as a value Y) of the cured coating film obtained in the above-mentioned transparency test was measured by a microscopic spectrometer, Model OSP-SP200, manufactured by OLYMPUS OPTICAL CO., LTD. (the value Y in this case is referred to as Y1). After heating the cured coating film at 280° C. for 30 minutes, the value Y of the cured coating film was measured by the above-mentioned apparatus (the value Y in this case is referred to as Y2). The heat resistance of the cured coating film was evaluated by a difference ΔY between Y1 and Y2. Samples which showed ΔY of less than 0.5 were rated “A”, while samples which showed ΔY of 0.5 or more were rated “C”.

Heat Resistance-2

Maximum light transmittance of the cured coating film obtained in the above-mentioned transparency test was measured by the above-mentioned apparatus. After heating of the cured coating film at 280° C. for 30 minutes, maximum light transmittance of the cured coating film was measured. The heat resistance of the cured coating film was evaluated by a rate of change expressed by ((A−B)/A)×100 where (A) is a value of maximum light transmittance of the cured coating film before heating, and (B) is a value of maximum light transmittance of the cured coating film after heating. Samples which showed a change of less than 5% were rated “A”, while samples which showed a change of 5% or more were rated “C”. Maximum light transmittance was measured by that microscopic spectrometer, Model OSP-SP200.

Chemical Resistance-1

The cured coating film obtained in the above-mentioned transparency test was dipped in N-methyl-2-pyrrolidone at 23° C. for 30 minutes. The boundary surface of the portion of the cured coating film dipped in the solution was observed. Samples wherein the boundary line can be visually confirmed were rated “C”, while samples wherein the boundary line could not be visually confirmed were rated “A”.

Chemical Resistance-2

The cured coating film obtained in the above-mentioned transparency test was rubbed with a cloth impregnated with acetone at 25° C. under a load of 0.5 kg using a rubbing tester (manufactured by Taihei Rika Industries Co., Ltd.) and the number of rubbing operations required until the glass substrate as a backing was exposed was observed. Samples which showed the number of rubbing operations of less than 100 were rated “C”, samples which showed the number of rubbing operations of 100 to less than 300 were rated “B”, samples which showed the number of rubbing operations of 300 to less than 500 were rated “A”, and samples which showed the number of rubbing operations of 500 or more were rated “AA”, respectively.

Preparation Example-1 (Preparation of Vinyl Polymer (A))

In a four-necked flask equipped with a thermometer, a reflux condenser, a stirrer and a nitrogen gas inlet, 425.0 parts of propylene glycol monomethyl ether acetate (hereinafter referred to as PGMAc) was charged and, after heating to 90° C. while stirring, a mixture of 82.0 parts of 2,3-carbonatepropyl methacrylate (hereinafter referred to as CPMA), 38.0 parts of methacrylic acid (hereinafter referred to as MAA), 210.0 parts of benzyl methacrylate (hereinafter referred to as BZMA), 97.0 parts of PGMAc and 16.5 parts of t-butylperoxy-2-ethylhexanate (hereinafter referred to as P-O) was added dropwise over one hour. After the completion of the dropwise addition, the mixture was maintained at 90° C. for 2 hours and 1.7 parts of P-O was added, and then the reaction was carried out at the same temperature for 7 hours to obtain a vinyl polymer (A-1) having an acid value (the number of milligrams of potassium hydroxide required to neutralize the acid content in 1 g of a sample, which is determined by a prescribed method) of 75 mg KOH/g of the resin solid content. The resulting solution had a non-volatile content (% by weight of residual resin after drying at 107.5° C. for one hour) of 40.7%, a Gardner viscosity of T-U, a number-average molecular weight (relative to polystyrene standards) of 5300, and Mw/Mn of 2.29.

Preparation Example-2 (Preparation of Vinyl Polymer (A))

In the same manner as in Preparation Example-1, except for replacing 38.0 parts of MAA by 76.0 parts, 210.0 parts of BZMA by 122.0 parts, 17.0 parts of 2-hydroxyethyl methacrylate (hereinafter referred to as HEMA) and 33.0 parts of styrene, P-O by 2,2′-azobis-(2,4-dimethylvaleronitrile) (hereinafter referred to as ADVN) as a polymerization initiator, 16.5 parts of P-O by 19.8 parts of ADVN, 1.7 parts of P-O by 1.7 parts of ADVN, the reaction temperature of 90° C. by 80° C., and the dropping time of one hour by 2 hours in Preparation Example-1, a vinyl polymer (A-2) having an acid value of 150 mg KOH/g of the resin solid content was obtained. The resulting solution had a non-volatile content of 41.0%, a Gardner viscosity of X-Y, a number-average molecular weight of 3700, and Mw/Mn of 3.55.

Preparation Example-3 (Preparation of Vinyl Polymer (A))

In the same manner as in Preparation Example-1, except for replacing 82.5 parts of CPMA by 25.0 parts of 3,4-carbonatebutyl acrylate, 49.5 parts of MAA by 38.0 parts, 209.5 parts of BzMA by 255.5 parts of methyl methacrylate, P-O by t-amylperoxy-2ethyl hexanoate (hereinafter referred to as TAEH) as a polymerization initiator, and 16.5 parts of P-O by 3.5 parts of TAEH in Preparation Example-1, a vinyl polymer (A-3) having an acid value of 98 mg KOH/g of the resin solid content was obtained. The resulting solution had a non-volatile content of 41.2%, a Gardner viscosity of Z2²-Z3, a number-average molecular weight of 11500, and Mw/Mn of 2.65.

Preparation Example-3 (Preparation of Comparative Copolymer)

In the same manner as in Preparation Example-1, except that CPMA in the mixture to be added dropwise was not used and 210.0 parts of BZMA was replaced by 292.0 parts in Preparation Example-1, a comparative copolymer (H-1) having an acid value of 75 mg KOH/g of the resin solid content was obtained. The resulting solution had a non-volatile content of 40.7%, a Gardner viscosity of H, a number-average molecular weight of 4800, and Mw/Mn of 2.40.

Preparation Example-4 (Preparation of Comparative Copolymer)

In the same reactor as in Preparation Example-1, 400.0 parts of PGMAc was charged and, after heating to 80° C. while stirring, a mixture of 66.4 parts of methacrylic acid, 196.9 parts of MMA, 113.9 parts of glycidyl methacrylate and 22.6 parts of P-O was added dropwise over one hour. After the completion of the dropwise addition, the mixture was maintained at 80° C. for one hour and 0.34 parts of P-O was added, and then reaction was carried out at the same temperature. After the completion of the dropwise addition of the monomer, however, the viscosity increased during the reaction went about 3 hours and the solution was finally gelled. Thus, a comparative copolymer (H-2) could not be obtained.

Preparation Example-5 (Preparation of Comparative Copolymer)

In the same manner as in Preparation Example-1, except for replacing 2,3-carbonatepropyl methacrylate in the mixture to be added dropwise by epoxycyclohexyl methacrylate (Cyclomer M-100, manufactured by Daicel Chemical Industries Co., Ltd.) and replacing the reaction temperature of 90° C. by 80° C. so as to prevent the gelation reaction from occurring during the polymerization in Preparation Example-1, the reaction was carried out. Two hours after the addition of P-O, a Gardner viscosity was Z1-Z2. At this time in point, a molecular weight was 11700 in terms of number-average, and a Mw/Mn was 6.86. Since the viscosity of the reaction solution gradually increased, the reaction was terminated within 5 hours by the addition of P-O to a comparative copolymer (H-3) having an acid value of 75 mg KOH/g of the resin solid content was obtained. The resulting solution had a non-volatile content of 40.7%, a Gardner viscosity of Z4-Z5, a number-average molecular weight of 12700, and Mw/Mn of 25.59. The resulting polymer exhibited wide molecular weight distribution.

Preparation Example-6 (Preparation of Comparative Copolymer)

In a flask equipped with a thermometer, a reflux condenser and a stirrer, 187 parts of bisphenol A epoxy resin having an epoxy equivalent weight of 187, 72 parts of acrylic acid and 1.2 parts of triphenylphosphine were charged and, after heating to 110° C. while stirring, the mixture was reacted at the same temperature until the acid value became 3 or less. Then, 152 parts of tetrahydrophthalic anhydride was added and the reaction was continued at 100° C. until the acid value became 137 to obtain a compound (H-4) having both a carboxyl group and an unsaturated double bond.

Preparation Example-7 (Preparation of Comparative Copolymer)

A flask equipped with a thermometer, a reflux condenser and a stirrer, 110 parts of glycerol-α-monochlorohydrin, 100 parts of dimethylformamide and 120 parts of sodium hydrogencarbonate were charged and, after heating to 100° C. while stirring, the mixture was reacted at the same temperature for 2 hours. Then, the insoluble matter and the solvent were removed to obtain a viscous liquid of hydroxymethylethylene carbonate.

In a flask equipped with a thermometer, a stirrer and a condenser, 118 parts of this hydroxymethylethylene carbonate was added and, after heating to 60° C. while stirring, 165 parts of isocyanurate-type polyisocyanate (NCO%=23.8%) of hexamethylene diisocyanate was added over one hour while paying attention to heat generation. The reaction was carried out for 10 hours and disappearance of absorption of an isocyanate group was confirmed by infrared absorption spectrum to obtain a desired compound (H-5) having a cyclocarbonate group.

Example 1

After diluting 100.0 parts of the vinyl polymer (A-1) obtained in Preparation Example-1 with 220.0 parts of PGMAc, 40.0 parts of dipentaerythritol hexaacrylate (hereinafter referred to as DPHA) and 1.2 parts of Irgacure 184 (manufactured by Ciba Speciality Chemicals Co., Ltd.) were weighed, followed by mixing with stirring until a uniform mixture was obtained. The resulting mixture was filtered through a filter having a pore diameter of 0.2 μm to obtain a photosensitive resin composition of the present invention. The storage stability of the resulting composition was evaluated. The results are shown in Table 1.

The resulting solution was applied on a glass plate while rotating at 1000 rpm for 9 seconds using a spin coater, and then preliminary dried at 60° C. for 5 minutes to form a previously dried coating film.

The preliminary dried coating film was exposed to light at a dose of 200 mJ/cm² using a high-pressure mercury lamp, and then cured by subjecting to a heat treatment at 230° C. for 15 minutes. Then, the transparency, heat resistance and chemical resistance of the coating film were evaluated. The evaluation results are shown in Table 1.

The previously dried coating film was exposed to light via a mask having a predetermined pattern at a dose of 200 mJ/cm² using a high-pressure mercury lamp, developed in an aqueous 1.0 wt % sodium carbonate solution at 30° C., and then was washed with pure water. In that case, it was evaluated whether or not a pattern having a line width of 20 μm could be formed (developing characteristics). The results are shown in Table 1.

Then, the patterned coating film was cured by subjecting to a heat treatment at 230° C. for 15 minutes using a hot plate.

Examples 2 to 5 and Comparative Examples 1 to 4

The same operation as in Example 1 was carried out, except for substitutions by substances shown in Table 1, resin compositions were obtained, and then various tests were carried out. The coating film performances are summarized in Table 1.

TABLE 1

| | | | Examples | | | | | Comparative Examples | | | |
|---|---|---|---|---|---|---|---|---|---|---|---|
| | | | 1 | 2 | 3 | 4 | 5 | 1 | 2 | 3 | 4 |
| Resin | Vinyl polymer solution | A-1 | 100 | 100 | 100 | — | — | — | Gelation | — | — |
| composition | Vinyl polymer solution | A-2 | — | — | — | 100 | — | — | | — | — |
| | Vinyl polymer solution | A-3 | — | — | — | — | 100 | — | | — | — |
| | Vinyl polymer solution | H-1 | — | — | — | — | — | 100 | | — | — |
| | Vinyl polymer solution | H-2 | — | — | — | — | — | — | | 100 | — |
| | Compound | H-3 | — | — | — | — | — | — | | — | 60 |
| | Compound | H-4 | — | — | — | — | — | — | | — | 20 |
| | DPHA | | 40 | 40 | — | 40 | 40 | 40 | | 40 | 40 |
| | PETA | | — | — | 40 | — | — | — | | — | — |
| | PGMAc | | 220 | 220 | 220 | 220 | 220 | 220 | | 220 | 280 |
| | Irg#184 | | 1.2 | 1.2 | 1.2 | 1.2 | 1.2 | 1.2 | | 1.2 | 1.2 |
| | Tetrabutylammonium bromide | | — | 0.2 | — | — | — | — | | — | — |
| | γ-glydoxypropyltrimethoxysilane | | — | 2.0 | — | — | — | — | | — | — |
| | Storage stability | | A | A | A | A | A | A | | C | A |
| Coating film | Developing characteristics | | A | A | A | A | A | A | | C | C |
| performances | Transparency | | A | A | A | A | A | A | | A | A |
| | Heat resistance-1 | | — | — | — | — | — | — | | — | — |
| | Heat resistance-2 | | A | A | A | A | A | C | | A | A |
| | Appearance of coating film after | | good | good | good | good | good | micro wavy | | good | good |
| | heat resistance test | | | | | | | surface | | | |
| | Chemical resistance-1 | | A | A | A | A | A | A | | A | A |
| | Chemical resistance-2 | | A | AA | A | A | A | A | | A | A |

Example 6

Using a high-speed disperser, Model “TSG-6H”, manufactured by Igarashi Machine Industry Co., Ltd., a dispersion comprising 25.0 parts of the vinyl polymer (A-1) prepared in Preparation Example-1, 8.0 parts of C.I. Pigment Red 254 (having a primary particle diameter of 80 nm or less), 2.5 parts of DISPERBYC 161 (resin-type dispersant), and 64.5 parts of PGMAc was dispersed at 2000 rpm for 8 hours using 0.5 mmø zirconia beads to obtain a red pigment dispersion. 100 Parts of the red pigment dispersion thus obtained was mixed with 7.0 parts of DPHA and 0.3 parts of Irgacure 369 (manufactured by Ciba Speciality Chemicals Co., Ltd.) and the mixture was filtered through a filter having a pore diameter of 1.0 μm to obtain a photosensitive resist of the present invention.

25 g of the resulting photosensitive resist was transferred into an airtight glass container and stored at 40° C. for 24 hours, and then the storage stability was evaluated.

The resulting photosensitive resist was applied on a glass plate while rotating at 1000 rpm for 9 seconds using a spin coater, and then preliminary dried at 60° C. for 5 minutes to form a previously dried coating film.

The preliminary dried coating film was exposed to light at a dose of 200 mJ/cm² using a high-pressure mercury lamp, and then cured by subjecting to a heat treatment at 230° C. for 15 minutes. Then, the transparency, heat resistance and chemical resistance of the coating film were evaluated. The evaluation results are shown in Table 2.

The preliminary dried coating film was exposed to light via a mask having a predetermined pattern at a dose of 100 mJ/cm² using a high-pressure mercury lamp, developed in an aqueous 0.5 wt % sodium carbonate solution at 30° C., and then washed with pure water. In this case, it was evaluated whether or not a pattern having a line width of 20 μm can be formed (developing characteristics).

Then, the picture element portion thus obtained was cured by subjecting to a heat treatment at 230° C. for 15 minutes using a hot plate.

Comparative Examples 5 to 6

In the same manner as in Example 6, except for replacing by substances shown in Table 2, red pigment dispersions were prepared to obtain photosensitive resists. In the same manner, various tests were carried out. The resulting performances are summarized in Table 2.

TABLE 2

| | | | Examples | Comparative Examples | | |
|---|---|---|---|---|---|---|
| | | | 6 | 5 | 6 | 7 |
| Photosensitive resist | Vinyl polymer solution | A-1 | 25 | — | — | — |
| | Vinyl polymer solution | A-2 | — | — | — | — |
| | Vinyl polymer solution | A-3 | — | — | — | — |
| | Vinyl polymer solution | H-1 | — | 25 | — | — |
| | Vinyl polymer solution | H-2 | — | — | — | — |
| | Vinyl polymer solution | H-3 | — | — | 25 | — |
| | Compound | H-4 | — | — | — | 10 |
| | Compound | H-5 | — | — | — | 7 |
| | C.I. Pigment Red 254 | | 8 | 8 | 8 | 8 |
| | DISPERBYC 161 | | 2.5 | 2.5 | 2.5 | 2.5 |
| | DPHA | | 7 | 7 | 7 | — |
| | PGMAc | | 64.5 | 64.5 | 64.5 | 79.5 |
| | Irg#369 | | 0.3 | 0.3 | 0.3 | 0.3 |
| | Storage stability | | A | A | C | C |
| Coating film | Developing characteristics | | A | A | C | C |
| performances | Transparency | | A | A | A | C |
| | Heat resistance-1 | | A | C | A | A |
| | Heat resistance-2 | | A | C | A | A |
| | Appearance of coating film after heat | | good | micro wavy | good | good |
| | resistance test | | | surface | | |
| | Chemical resistance-1 | | A | A | A | A |
| | Chemical resistance-2 | | A | A | A | A |

### INDUSTRIAL APPLICABILITY

The photosensitive resin composition of the present invention has good storage stability and excellent transparency because it contains a vinyl polymer having a cyclocarbonate group and a carboxyl group, and is also capable of yielding a coating film having excellent heat resistance and chemical resistance by ultimately allowing the cyclocarbonate group and the carboxyl group to react, thereby introducing a crosslinked structure. The photosensitive resin composition can be used as coating compositions, printing ink and resists, and is particularly useful as a photosensitive resist for color filters.

The photosensitive resist for color filters of the present invention contains a vinyl polymer having a cyclocarbonate group and a carboxyl group and both having an ethylenically unsaturated double bond and is capable of introducing a crosslinked structure formed by photocuring and thermosetting into the picture element portion of the color filter, and is useful to form a durable picture element portion of the color filter.

The method for producing color filters of the present invention is a useful method for production of a color filter having excellent durability because the above-mentioned photosensitive resist for color filter is used.

1. A photosensitive resin composition comprising a vinyl polymer (A) having at least one 2-oxo-1,3-dioxoran-4-yl group and at least one carboxyl group in the molecule, and a compound (B) having at least two ethylenically unsaturated double bonds in the molecule as a main component.

2. The photosensitive resin composition according to claim 1, wherein the vinyl polymer (A) is an acrylic resin.

3. The photosensitive resin composition according to claim 1 or 2, wherein the vinyl polymer (A) having at least one 2-oxo-1,3-dioxoran-4-yl group and at least one carboxyl group in the molecule comprises a (meth)acrylate ester having an aromatic ring as a copolymer component.

4. The photosensitive resin composition according to claim 3, wherein the (meth)acrylate ester having an aromatic ring is a benzyl (meth)acrylate.

5. A photosensitive resist for color filter, comprising a vinyl polymer (A) having at least one 2-oxo-1,3-dioxoran-4-yl group and at least one carboxyl group in the molecule, a compound (B) having at least two ethylenically unsaturated double bonds in the molecule, and a colorant (C) as a main component.

6. A method for producing a color filter, which comprises forming a resist layer on a transparent substrate using a photosensitive resist for color filter comprising a vinyl polymer (A) having at least one 2-oxo-1,3-dioxoran-4-yl group and at least one carboxyl group in the molecule, a compound (B) having at least two ethylenically unsaturated double bonds in the molecule, and a colorant (C) as a main component; exposing the resist layer to light via a mask having a picture element pattern for color filter, thereby to photocure the resist layer; developing the resist layer to form a picture element portion; and heating the picture element portion, thereby to thermoset the picture element portion.
